(19) United States
(12) Patent Application Publication
(10) Pub. No.: US 2021/0335531 A1
(43) Pub. Date: Oct. 28, 2021

(54) INDEPENDENT TYPE INSTANTANEOUS CURRENT DETECTION PCB CT DEVICE APPLIED TO BREAKER

(71) Applicant: COBONTECH CO., LTD., Cheongju-si, Chungcheongbuk-do (KR)

(72) Inventors: Inki RYU, Chungcheongbuk-do (KR); Yeunsook JOO, Chungcheongbuk-do (KR)

(21) Appl. No.: 16/610,447

(22) PCT Filed: Aug. 21, 2019
(86) PCT No.: PCT/KR2019/010623

§ 371 Date: Nov. 1, 2019

(30) Foreign Application Priority Data
Aug. 28, 2018 (KR) 10-2018-0101194

(51) Int. Cl. H01F 27/28; H05K 1/11; H05K 1/16; H01F 27/24; H01F 41/04; H01F 38/30; G01R 15/18

(52) U.S. Cl. CPC H01F 27/2804; H05K 1/115; H05K 1/165; H01F 27/24; H01F 2027/2809; H01F 38/30; G01R 15/181; H05K 2201/10151; H01F 41/041

(57) ABSTRACT

The present invention relates to an independent type instantaneous current detection PCB CT device applied to a breaker, and more particularly relates to an independent type instantaneous current detection PCB CT device including a coil pattern-based PCB type air-core coil sensor mounted on a main PCB formed in the breaker or configured independently of the breaker.

### TECHNICAL FIELD

The present invention relates to an independent type instantaneous current detection PCB CT device applied to a breaker, and more particularly relates to an independent type instantaneous current detection PCB CT device including a coil pattern-based PCB type air-core coil sensor mounted on a main PCB formed in the breaker or configured independently of the breaker.

### BACKGROUND ART

In current measuring methods, devices and methods have been developed to measure current in a wide variety of ways including current transformers, shunts, hall sensors and Rogowski coils etc.

The most common current measuring method for measuring the load current and the fault current in power devices such as switchboards and various high-voltage switchgears is to use a CT (Current Transformer) of winding a coil around an iron core.

However, since the CT is manufactured by using the iron cores, if the current measurement range increases according to the physical characteristics (electromagnetic induction phenomena, iron loss due to hysteresis) of the material itself, it is out of the measurement error thereof, so that there is a difficult problem of malfunction or non-operation in use.

In order to prevent a saturation in the CT, high quality materials can be used or the amount of the iron cores can be increased. However, if it is used over a certain amount, it is difficult to manufacture the CT. Also, the volume of accommodating the CT is excessively increased and heavy, resulting in many problems in use.

Also, in order to use in electrical devices such as a circuit breaker etc., “a zero phase current transformer having current transformer”, in that three current transformers (CT) for each phase (hereinafter referred to as a ‘CT’) and a zero phase sequence current transformer (hereinafter referred to as a ZCT) are integrally formed, is known.

The ZCT used commonly is a circular donut shape (annular shape). However, it is known to have a track shape instead of a circle shape in order to reduce the size of the device in the zero phase current transformer having current transformer.

The conventional zero phase current transformer having the current transformer can reduce the volume by integrating the zero phase current transformer and each current transformer in the main case.

On the other hand, an ELCB (Earth Leakage Circuit Breaker) is an assembly of integrally assembling a switchgear and a trip device, etc. in an insulator container. It can open and close the energized circuit by manual or electric operation. Also, it can automatically cut off the current in case of overload, disconnection, and short circuit.

Such an earth leakage circuit breaker is used for the purpose of preventing an electric shock and an electric fire caused by a short circuit in a low voltage circuit of AC 600V or less.

The earth leakage circuit breaker includes a printed circuit board, a mechanism unit for opening and closing the electric circuit by a mechanical operation, an arc extinguishing unit for extinguishing an arc generated when blocking thereof, a test switch for testing whether the earth leakage circuit breaker is normally operated or not, and an earth leakage trip etc.

The printed circuit board is equipped with an IC (Back Side Type, COB type), a resistor, a capacitor, a thyristor (SCR), and the like.

However, in the conventional earth leakage circuit breaker, the components such as the IC (back side type, COB type), the resistor, the capacitor, the thyristor (SCR) etc. are disposed on the printed circuit board. Also, the zero phase current transformer (ZCT) is disposed thereon.

At this time, due to the mechanical structural narrowness of the earth leakage circuit breaker, there is a limit in developing an earth leakage circuit breaker capable of blocking the short circuit or the overload even if they occur by introducing the CT device in addition to the ZCT.

Concretely, as shown in FIG. 1, a considerable space is required. However, in the conventional case, since two CT devices are configured in the same size as the ZCT device (because one CT device should be configured in one wire), there is a structural problem in that the ZCT device and the CT device cannot be configured into the case of the earth leakage circuit breaker at the same time.

For example, since the thickness of the ZCT device is 10 mm and the thickness of the CT device is 10 mm×2, a space for mounting the devices having a total thickness of about 30 mm thereon is required.

That is, as shown in FIG. 1, since the distance between the PCB (10) having the conventional ZCT device and the terminal (30), to which the wire (20) is coupled, is 10 mm, it is impossible to secure a space for constructing the CT devices and the like.

Accordingly, in order to secure the space to form the CT devices on the circuit breaker structure to improve the above problems, the present invention is to provide an independent type instantaneous current detection PCB CT device including a coil pattern-based PCB type air-core coil sensor mounted on a main PCB formed in a breaker, or configured independently of the breaker.

### PATENT LITERATURE

Patent Literature 1: Korea Patent Registration No. 10-0918110

### DISCLOSURE

### Technical Problem

Accordingly, the present invention has been made to solve the above conventional problem, and an object of the present invention is to provide an independent type instantaneous current detection PCB CT device including a coil pattern-based PCB type air-core coil sensor mounted on a main PCB formed in a breaker to ensure a space for forming the CT device on a breaker structure, or configured independently of the breaker.

Another object of the present invention is to improve a humidity-resistant characteristic and reliability of product performance by configuring an independent type instantaneous current detection PCB CT device including a PCB type air-core coil sensor in an earth leakage breaker case having a narrow space so that various analog parts are integrated on a PCB corresponding to a printed circuit board.

Still another object of the present invention is to allow elimination of coil winding work by providing an independent type instantaneous current detection PCB CT device including a PCB type air-core coil sensor, allow improvement of a humidity-resistant characteristic and reliability of product performance by integrating various analog parts on a PCB corresponding to a printed circuit board, and allow provision of mass productivity of a product by integrating various analog parts to simplify a circuit work process.

### Technical Solution

According to one aspect of the present invention so as to accomplish these objects, there is provided to an independent type instantaneous current detection PCB CT device applied to a breaker mounted on a main PCB formed in the breaker or formed independently of the breaker by including a donut-shaped PCB (3000a) including a first through-hole portion (3100a); and a PCB type air-core coil sensor (1000a) for detecting a current of a first electric wire (L1) passing through the first through-hole portion (3100a) by a plurality of inner via-holes (1100a) formed at a certain interval on an outside of the first through-hole portion (3100a) formed in the PCB (3000a), a plurality of outer via-holes (1200a) formed at a certain interval at locations spaced apart from the inner via-holes by certain intervals, and the inner via-holes and the outer via-holes connected by a coil pattern (1300a).

### Advantageous Effects

According to the independent type instantaneous current detection PCB CT device applied to a breaker, by providing the independent type instantaneous current detection PCB CT device including the coil pattern-based PCB type air-core coil sensor mounted on the main PCB formed in the breaker to ensure a space for forming the CT device on the breaker structure or configured independently of the breaker through the above-described configuration and operation, the breaker is provided to have an instantaneous detection function for blocking a short circuit or an overload when the short circuit or the overload occurs. Thus, a problem of a conventional art in which various current detection functions may not be performed due to lack of space is compensated, thereby providing an instantaneous function for simultaneously detecting a short circuit and an overload current.

Also, as the independent type instantaneous current detection PCB CT device including the PCB type air-core coil sensor is configured inside the narrow earth leakage breaker case, and thus various analog parts are integrated on the PCB corresponding to the printed circuit board, it is effective in improving a humidity-resistant characteristic and reliability of product performance.

In addition, the present invention is to allow elimination of coil winding work by providing an independent type instantaneous current detection PCB CT device including a PCB type air-core coil sensor, allow improvement of a humidity-resistant characteristic and reliability of product performance by integrating various analog parts on a PCB corresponding to a printed circuit board, and allow provision of mass productivity of a product by integrating various analog parts to simplify a circuit work process.

In addition, due to provision in the form of the PCB, slimming down and reduction in space can be achieved, thereby providing a cost reduction effect.

In addition, by eliminating the conventional coil winding work, it is effective in making an electric characteristic constant (uniform) and increasing affinity for making a finished product.

### BRIEF DESCRIPTION OF DRAWINGS

The above and other objects, features and advantages of the present invention will be more apparent from the following detailed description taken in conjunction with the accompanying drawings, in which:

FIG. 1 is a photograph showing a conventional circuit breaker;

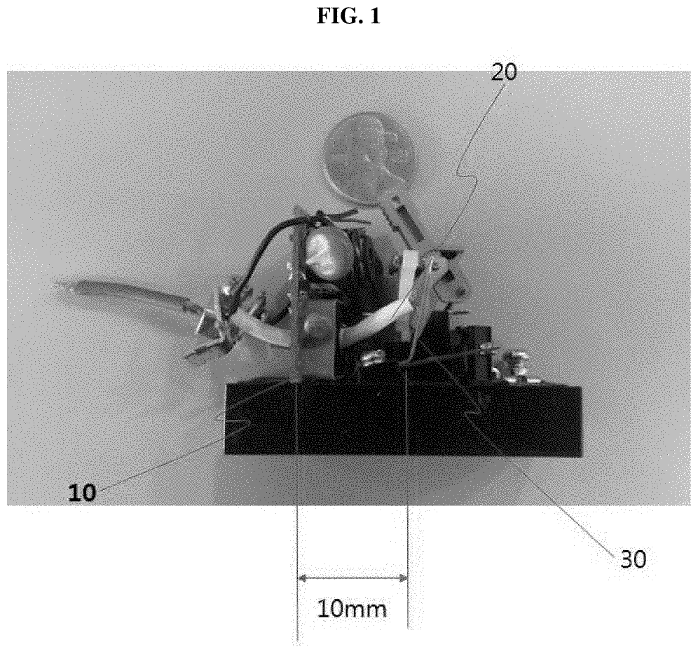

FIG. 2 is a schematic configuration diagram of an independent type instantaneous current detection PCB CT device applied to a breaker according to a first embodiment of the present invention;

FIG. 3 is an actual photograph thereof;

FIG. 4 is a schematic configuration diagram of an independent type instantaneous current detection PCB CT device applied to a breaker according to a second embodiment of the present invention;

FIG. 5 is an actual photograph thereof;

FIG. 6 is an illustrative view illustrating stacking of respective layers of the PCB type air-core coil sensor (1000a) or the PCB type first air-core coil sensor (1000) and the PCB type second air-core coil sensor (2000) of the independent type instantaneous current detection PCB CT device applied to the breaker according to the first embodiment or the second embodiment of the present invention;

FIG. 7 is an illustrative view of stacking for forming the PCB type first air-core coil sensor (1000), the PCB type second air-core coil sensor (2000), and the PCB type air-core coil sensor (1000a) on the PCBs (3000 and 3000a) of the independent type instantaneous current detection PCB CT device applied to the breaker according to the first embodiment or the second embodiment of the present invention;

FIG. 8 is a schematic configuration diagram of an independent type instantaneous current detection PCB CT device applied to a breaker according to a third embodiment of the present invention;

FIG. 9 is an actual photograph thereof.

FIG. 10 is an illustrative view illustrating stacking of respective layers of the PCB type air-core coil sensor (1000a) or the PCB type first air-core coil sensor (1000) and the PCB type second air-core coil sensor (2000) of the independent type instantaneous current detection PCB CT device applied to the breaker according to the third embodiment of the present invention;

FIG. 11 is an illustrative view of stacking for forming the PCB type first air-core coil sensor (1000) and the PCB type second air-core coil sensor (2000) on the PCB (3000) of the independent type instantaneous current detection PCB CT device applied to the breaker according to the third embodiment of the present invention;

FIG. 12 is an illustrative view illustrating the conventionally external CT device;

FIG. 13 is an illustrative view illustrating an external view when the independent type instantaneous current detection PCB CT device applied to the breaker according to the first embodiment to the third embodiment is applied to a one-phase to three-phase four-wire system;

FIG. 14 is an illustrative view illustrating a state in that the independent type instantaneous current detection PCB CT device applied to the breaker according to the first embodiment to the third embodiment is mounted on the main PCB and the ZCT device is mounted thereon; and

FIG. 15 is a schematic configuration diagram of an independent type instantaneous current detection PCB CT device applied to a breaker according to a fourth embodiment of the present invention.

### REFERENCE SIGNS LIST

1000: PCB type first air-core coil sensor
2000: PCB type second air-core coil sensor
3000: PCB

### BEST MODE

### Mode for Invention

Hereinafter, an independent type instantaneous current detection PCB CT device applied to a breaker according to the present invention will be described in detail through embodiments.

Currently, a general breaker includes a ZCT, and there is a shunt or a busbar penetrating through ZCT.

In particular, a mechanical structure is complicated, and thus a space is narrow. In the structure, an electric wire passes through a center hole of the ZCT so that a space is tight (narrow), and there is no extra space.

Therefore, it is impossible to introduce a CT device for detecting an overload, and thus it is impossible to perform an additional function other than a function of an earth leakage breaker.

However, the present invention provides an independent type instantaneous current detection PCB CT device, thereby providing an advantage that an installation configuration is allowed even in a narrow space.

Preferably, the independent type instantaneous current detection PCB CT device of the present invention can be slimmed down to a diameter of 10 mm or less and a thickness of 1 mm or less.

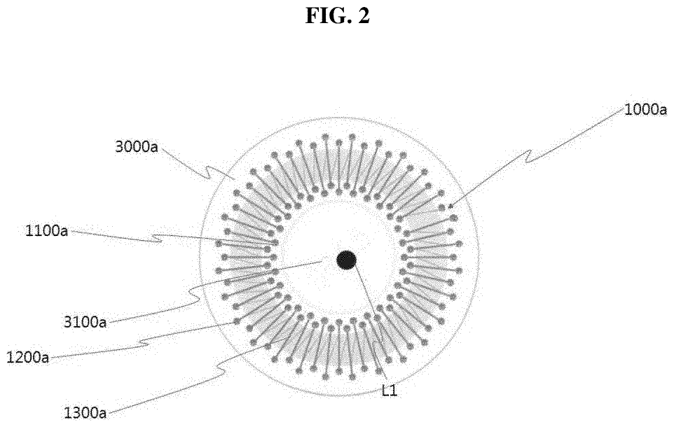

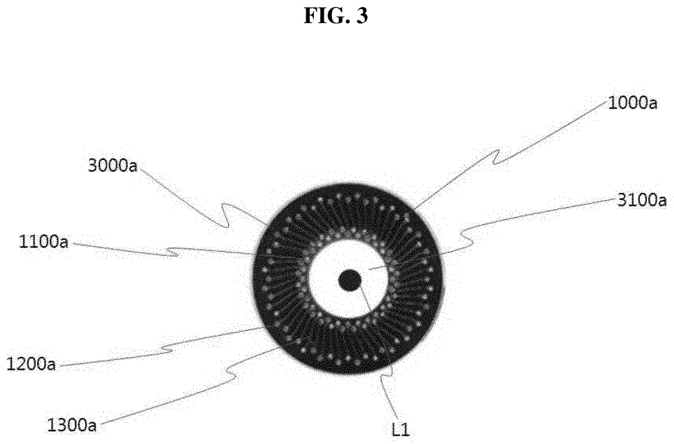

FIG. 2 is a schematic configuration diagram of an independent type instantaneous current detection PCB CT device applied to a breaker according to a first embodiment of the present invention, and FIG. 3 is an actual photograph.

As illustrated in FIG. 2 and FIG. 3, the independent type instantaneous current detection PCB CT device applied to the breaker of the present invention largely includes a PCB (3000a) and a PCB type air-core coil sensor (1000a).

In this instance, in general, a ZCT device, a COB-IC circuit part, a trip coil, a trip coil switch, etc. are included on a main PCB. Here, the independent type instantaneous current detection PCB CT device of the present invention is formed in the breaker to provide a detected current value to the COB-IC circuit part.

Since a mechanical structure of the breaker other than the above construction means is a general technology, detailed description thereof will be omitted.

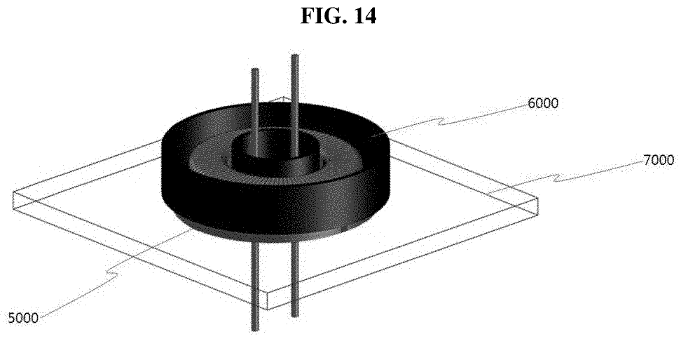

As illustrated in FIG. 14, a general ZCT device performs a function of detecting a leakage current of an electric wire passing through a through-hole and transmitting a detection signal to a COB-IC circuit unit.

As illustrated in FIG. 14, in general, the ZCT device has a form in which a through-hole is formed in a center, and a coil is directly wound by a worker and formed along a circumference of the through-hole so that electric wires for detecting a current of accidence such as grounding or an electric shock penetrates through the through-hole.

Specifically, the donut-shaped PCB (3000a) of the present invention is configured to include a through-hole portion (3100a).

In this instance, the PCB type air-core coil sensor (1000a) is configured. Specifically, a plurality of inner via-holes (1100a) are formed at a certain interval on the outside of the through-hole portion (3100a) formed in the PCB (3000a), a plurality of outer via-holes (1200a) are formed at a certain interval at locations spaced apart from the inner via-holes by certain intervals, and the inner via-holes and the outer via-holes are connected by a coil pattern (1300a).

Therefore, a current of a first electric wire (L1) passing through the through-hole portion (3100a) is detected.

The independent type instantaneous current detection PCB CT device of the present invention configured as described above is mounted on the main PCB formed in the breaker, or is formed independently of the breaker.

In the case of conventional breakers, the CT device may not be applied to a space since the space is narrow, and thus merely a configuration for detecting a leakage current is provided, and an overload current may not be detected. However, in the case of the independent type PCB CT device of the present invention, the size is 1.5 cm or less and the thickness is 0.1 cm or less, and thus it is advantageous in that the CT device can be applied to any breaker having a narrow space.

In general, the COB-IC circuit part is formed on the main PCB. When the ZCT device is formed as illustrated in FIG. 14, a COB IC, a resistor, a capacitor, and a thyristor are integrated in the printed circuit board to provide a trip signal to a trip coil when a leakage current is generated by detecting a leakage current provided from the ZCT device or to provide a trip signal to a trip coil when an overload current is generated by detecting a current provided from the independent type instantaneous current detection PCB CT device.

In the COB-IC circuit part, providing a trip signal to a trip coil when a leakage current is generated or providing a trip signal to a trip coil when an overload current is generated is a conventionally general technology, and thus those skilled in the art will fully understand a scheme of providing a trip signal even when a detailed description is omitted.

In this instance, a commonly known trip coil performs a function of opening a trip coil switch to cut off power when a trip signal is acquired from the COB-IC circuit part, and the trip coil switch is opened by the trip coil to cut off power supply from a first electric wire (L1) and a second electric wire (L2).

A configuration of the breaker according to the an embodiment of the present invention is applied in a state in which a space is ensured in the breaker case, that is, in a state in which a space for constructing an air-core coil sensor for detecting an overload current is ensured, and thus may have a disadvantage of having to be formed larger than a size of a conventional case.

Therefore, application to a ready-made product may be difficult, and thus this problem can be solved by provision in the form of the PCB through the present invention.

Meanwhile, the breaker described in the present invention is characterized by corresponding to any one of an earth leakage breaker, a general breaker, and a two-way earth leakage breaker.

In other words, it is possible to provide a slim type to a variety of breakers.

In addition, the independent type instantaneous current detection PCB CT device of the present invention is characterized by being located in a through-hole in a main PCB (7000) in which a ZCT device (6000) is formed and thus applicable to the breaker so that at least one or more of a short circuit and an overload current can be detected.

Specifically, as illustrated in FIG. 14, an independent type instantaneous current detection PCB CT device (5000) is formed on an upper side of the through-hole formed in the main PCB (7000). In this instance, the ZCT device is formed on an upper side of the independent type instantaneous current detection PCB CT device.

Therefore, when the independent type instantaneous current detection PCB CT device (5000) formed in the printed pattern is configured in the through-hole in the main PCB in which the ZCT device is formed, application to the breaker is allowed, so that at least one or more of a short circuit and an overload current can be detected.

The above-described configuration can provide a synergistic effect that can solve a conventional narrow space problem at once.

In addition, for example, when the breaker is the earth leakage breaker, a variety of analog parts are integrated in the PCB corresponding to the printed circuit board by simultaneously configuring the ZCT device and the independent type instantaneous current detection PCB CT device (5000) that may detect an overload inside an earth leakage breaker case having a narrow space. Accordingly, it is effective in improving a humidity-resistant characteristic and reliability of product performance.

In addition, when the independent type instantaneous current detection PCB CT device (5000) having a PCB structure and the COB-IC circuit part having a PCB structure are configured in the breaker, coil winding work can be eliminated. As various analog parts are integrated in the PCB corresponding to the printed circuit board, the humidity-resistant characteristic and the reliability of product performance can be improved. As various analog parts are integrated, a circuit work process is simplified, and thus it is effective in providing mass productivity of a product.

In addition, due to provision in the form of the PCB, slimming down and reduction in space can be achieved, thereby providing a cost reduction effect.

In addition, when the conventional coil winding work is eliminated, it is effective in making an electric characteristic constant (uniform) and increasing affinity for making a finished product.

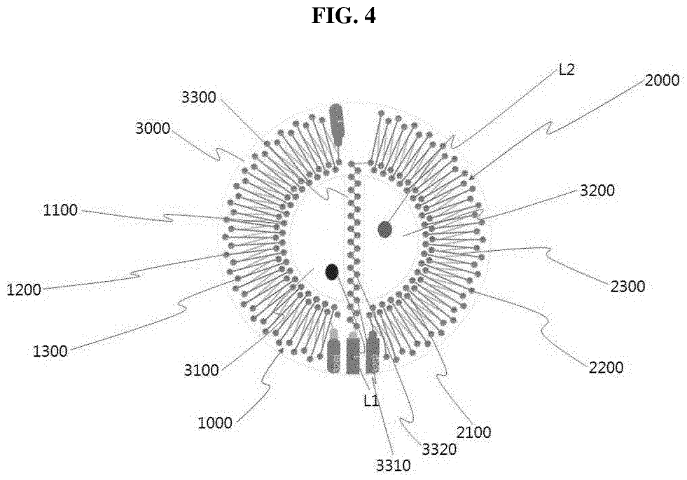

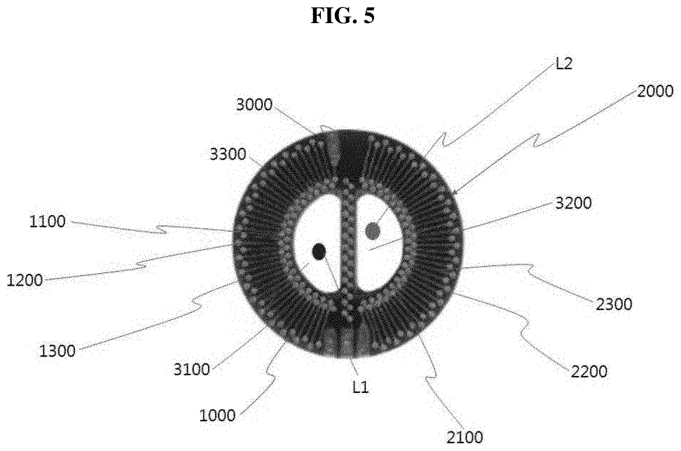

FIG. 4 is a schematic configuration diagram of an independent type instantaneous current detection PCB CT device applied to a breaker according to a second embodiment of the present invention, and FIG. 5 is an actual photograph.

As illustrated in FIG. 4 and FIG. 5, the independent type instantaneous current detection PCB CT device applied to the breaker according to the second embodiment is characterized by being mounted on a main PCB formed in the breaker or formed independently of the breaker by including a PCB (3000) including a first through-hole portion (3100) formed on one side of a partition and a second through-hole portion (3200) formed on the other side of the partition with the partition (3300) interposed therebetween, a PCB type first air-core coil sensor (1000) for detecting a current of a first electric wire (L1) passing through the first through-hole portion (3100) by a plurality of inner via-holes (1100) being formed at a certain interval on the outside of the first through-hole portion (3100) formed in the PCB (3000), a plurality of outer via-holes 1200 formed at a certain interval at locations spaced apart from the inner via-holes by certain intervals, and the inner via-holes and the outer via-holes connected by a coil pattern (1300), and a PCB type second air-core coil sensor (2000) for detecting a current of a second electric wire (L2) passing through the second through-hole portion (3200) by a plurality of inner via-holes (2100) being formed at a certain interval on the outside of the second through-hole portion (3200) formed in the PCB (3000), a plurality of outer via-holes (2200) formed at a certain interval at locations spaced apart from the inner via-holes by certain intervals, and the inner via-holes and the outer via-holes connected by a coil pattern (2300).

Specifically, the PCB (3000) includes the first through-hole portion (3100) formed on one side of the partition and the second through-hole portion (3200) formed on the other side of the partition with the partition (3300) interposed therebetween.

In this instance, the PCB type first air-core coil sensor (1000) is configured such that the plurality of inner via-holes (1100) are formed at a certain interval on the outside of the first through-hole portion (3100) formed in the PCB (3000), the plurality of outer via-holes 1200 are formed at a certain interval at locations spaced apart from the inner via-holes by certain intervals, and the inner via-holes and the outer via-holes are connected by a coil pattern (1300).

Therefore, the current of the first electric wire (L1) passing through the first through-hole portion (3100) is detected.

Further, the PCB type second air-core coil sensor (2000) is configured such that the plurality of inner via-holes (2100) are formed at a certain interval on the outside of the second through-hole portion (3200) formed in the PCB (3000), the plurality of outer via-holes (2200) are formed at a certain interval at locations spaced apart from the inner via-holes by certain intervals, and the inner via-holes and the outer via-holes are connected by a coil pattern (2300).

Therefore, the current of the second electric wire L2 passing through the second through-hole portion (3200) is detected.

Meanwhile, in the partition (3300), a plurality of partition via-holes (3310) are formed at a certain interval, and one of the partition via-holes and another one of the partition via-holes are connected by a coil pattern (3320).

As described above, when the coil pattern is formed in the partition, a large current can be detected.

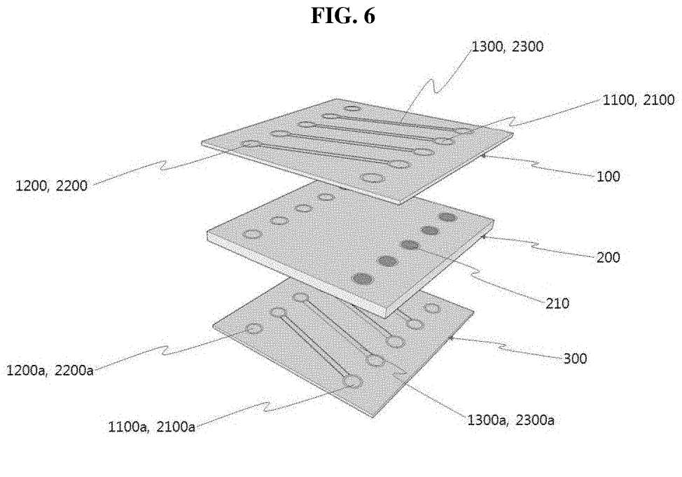

FIG. 6 is an illustrative view illustrating stacking of respective layers of the PCB type air-core coil sensor (1000a) or the PCB type first air-core coil sensor (1000) and the PCB type second air-core coil sensor (2000) of the independent type instantaneous current detection PCB CT device applied to the breaker according to the first embodiment or the second embodiment of the present invention.

As illustrated in FIG. 6, the PCB type air-core coil sensor (1000a) or the PCB type first air-core coil sensor (1000) and the PCB type second air-core coil sensor (2000) are characterized by including an upper coil pattern forming layer (100) formed of a nonmagnetic material and having a plurality of coil patterns (1300 and 2300) connected through the inner via-holes (1100 and 2100) and the outer via-holes (1200 and 2200) alternately from the upper side to the lower side and from the lower side to the upper side, an insulator (200) disposed below the upper coil pattern forming layer to have a plurality of via-holes (210) having the same size as that of the inner via-holes (1100 and 2100) and the outer via-holes (1200 and 2200) at positions thereof on both sides, and a lower coil pattern forming layer (300) located below the insulator, formed of a nonmagnetic material, and having a plurality of coil patterns (1300a and 2300a) connected through a plurality of inner via-holes (1100a and 2100a) and outer via-holes (1200a) and 2200a) alternately from the upper side to the lower side and from the lower side to the upper side.

Specifically, the upper coil pattern forming layer (100) is characterized by being formed of a nonmagnetic material and having the plurality of coil patterns (1300 and 2300) connected through the inner via-holes (1100 and 2100) and the outer via-holes (1200 and 2200) alternately from the upper side to the lower side and from the lower side to the upper side.

In this instance, the insulator (200) is formed below the upper coil pattern forming layer to have the plurality of via-holes (210) having the same size as that of the inner via-holes (1100 and 2100) and the outer via-holes (1200 and 2200) at positions thereof on both sides.

In this instance, the lower coil pattern forming layer (300) is formed below the insulator, is formed of a nonmagnetic material, and has the plurality of coil patterns (1300a and 2300a) connected through the plurality of inner via-holes (1100a and 2100a) and outer via-holes (1200a and 2200a) alternately from the upper side to the lower side and from the lower side to the upper side.

Through the above configuration, the coil pattern of the upper coil pattern forming layer (100) provides a three-dimensional (3D) coil shape with a coil pattern formed on the lower side by being connected to the via-hole formed in the insulator (200) and the via-hole formed in the lower coil pattern forming layer (300).

Therefore, there is no need to perform handwork of winding coils one by one as in the past.

Meanwhile, the insulator is preferably formed of a pre-prog material.

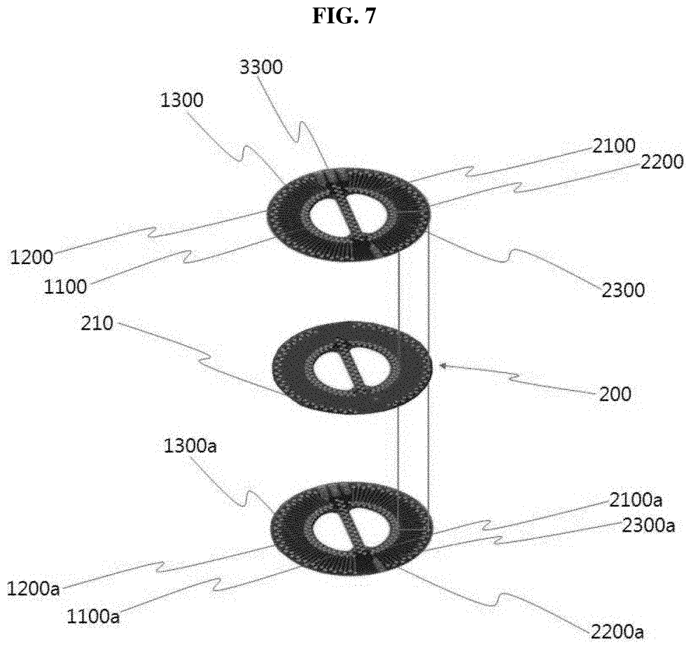

FIG. 7 is an illustrative view of stacking for forming the PCB type first air-core coil sensor (1000), the PCB type second air-core coil sensor (2000), and the PCB type air-core coil sensor (1000a) on the PCBs (3000 and 3000a), and coil patterns are formed while maintaining a certain interval. Therefore, an overall shape of the coil patterns has a coil wound shape, and thus it is possible to provide a uniform characteristic during mass production.

In addition, FIG. 7 is an illustrative view of stacking for a two-sphere shape, and may be an illustrative view of stacking for a one-sphere shape in the first embodiment. A difference therebetween is that the shape is divided into the one-sphere shape and the two-sphere shape depending on whether a partition is formed at a center of the through-hole.

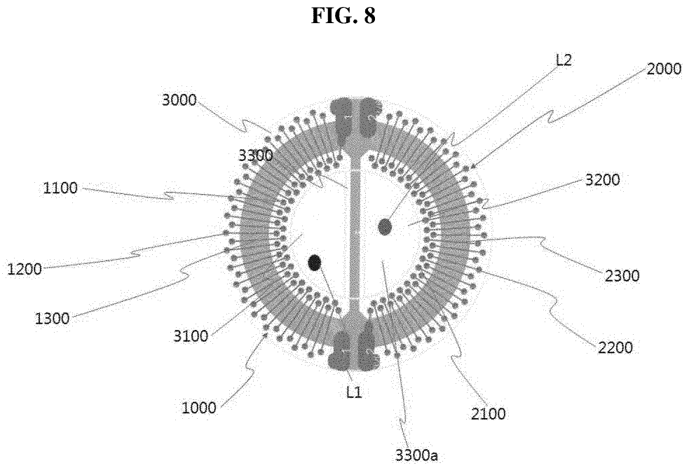

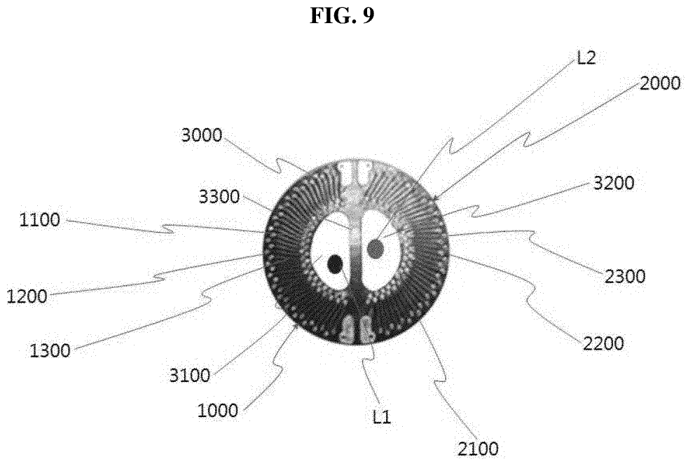

FIG. 8 is a schematic configuration diagram of an independent type instantaneous current detection PCB CT device applied to a breaker according to a third embodiment of the present invention, and FIG. 9 is an actual photograph.

As illustrated in FIG. 8 and FIG. 9, the independent type instantaneous current detection PCB CT device applied to the breaker of the present invention largely includes a PCB (3000), a PCB type first air-core coil sensor (1000), and a PCB type second air-core coil sensor (2000).

Since this embodiment has the same configuration as that of the second embodiment, a detailed description thereof will be omitted. A difference from the second embodiment is that a magnetic core needs to be formed in a CT device to perform low current detection.

Therefore, a characteristic is that a core layer (3300a) is formed inside a partition (3300) of the independent type instantaneous current detection PCB CT device corresponding to a two-sphere type.

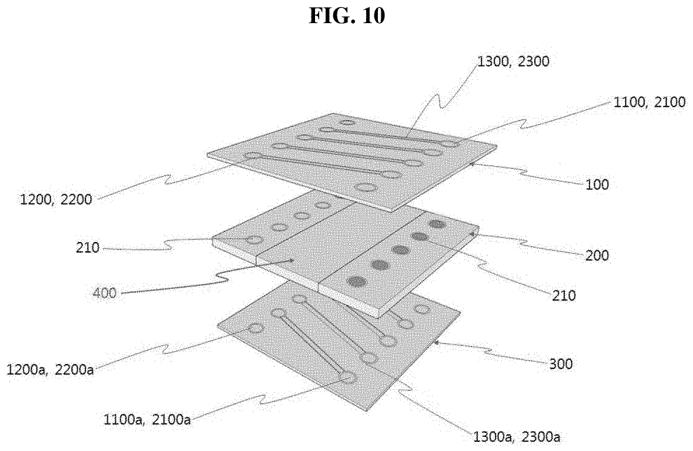

Since the partition is not present in the independent type instantaneous current detection PCB CT device corresponding to a one-sphere type according to the first embodiment, the core layer (3300a) is not applied. However, the core layer may be applied to the inside as in FIG. 10.

FIG. 10 is an illustrative view illustrating stacking of respective layers of the PCB type air-core coil sensor (1000a) or the PCB type first air-core coil sensor (1000) and the PCB type second air-core coil sensor (2000) of the independent type instantaneous current detection PCB CT device applied to the breaker according to the third embodiment of the present invention.

As illustrated in FIG. 10, the PCB type air-core coil sensor (1000a) or the PCB type first air-core coil sensor (1000) and the PCB type second air-core coil sensor (2000) are characterized by including an upper coil pattern forming layer (100) formed of a nonmagnetic material and having a plurality of coil patterns (1300 and 2300) connected through the inner via-holes (1100 and 2100) and the outer via-holes (1200 and 2200) alternately from the upper side to the lower side and from the lower side to the upper side, an insulator (200) disposed below the upper coil pattern forming layer to have a plurality of via-holes (210) having the same size as that of the inner via-holes (1100 and 2100) and the outer via-holes (1200 and 2200) at positions thereof on both sides, a magnetic core body (400) formed of a core material between the via-holes (210) formed on the both sides, and a lower coil pattern forming layer (300) located below the insulator, formed of a nonmagnetic material, and having a plurality of coil patterns (1300a and 2300a) connected through a plurality of inner via-holes (1100a and 2100a) and outer via-holes (1200a and 2200a) alternately from the upper side to the lower side and from the lower side to the upper side.

A difference from the second embodiment is that the magnetic core body is formed inside so that a low current can be detected.

Specifically, the upper coil pattern forming layer (100) is formed of a nonmagnetic material, and has a plurality of coil patterns (1300 and 2300) connected through the inner via-holes (1100 and 2100) and the outer via-holes (1200 and 2200) alternately from the upper side to the lower side and from the lower side to the upper side.

In this instance, the insulator (200) is disposed below the upper coil pattern forming layer to have a plurality of via-holes (210) having the same size as that of the inner via-holes (1100 and 2100) and the outer via-holes (1200 and 2200) at positions thereof on both sides.

In particular, the magnetic core body (400) is formed of a core material between the via-holes (210) formed on the both sides.

In addition, the lower coil pattern forming layer (300) is located below the insulator, and formed of a nonmagnetic material.

Further, a plurality of coil patterns (1300a and 2300a) are formed to be connected through a plurality of inner via-holes (1100a and 2100a) and outer via-holes (1200a and 2200a) alternately from the upper side to the lower side and from the lower side to the upper side.

Through the above configuration, the coil pattern of the upper coil pattern forming layer (100) provides a 3D coil shape with a coil pattern formed on the lower side by being connected to the via-hole formed in the insulator (200) and the via-hole formed in the lower coil pattern forming layer (300).

Meanwhile, Ni—Fe-based permalloy is used as the magnetic core body (400) described in the present invention.

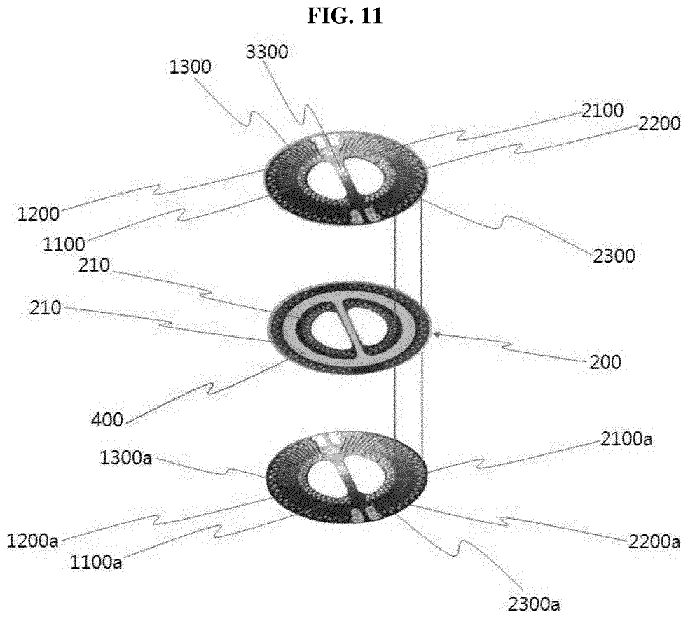

FIG. 11 is an illustrative view of stacking for forming the PCB type first air-core coil sensor (1000) and the PCB type second air-core coil sensor (2000) on the PCB (3000), and coil patterns are formed while maintaining a certain interval. Therefore, an overall shape of the coil patterns has a coil wound shape, and thus it is possible to provide a uniform characteristic during mass production.

FIG. 11 is an illustrative view of stacking according to the second embodiment, and also corresponds to an example of stacking according to the first embodiment. A difference therebetween is that a partition is or is not formed at the center of the through-hole.

As a result, through the above-described configuration, the instantaneous current detection PCB integrated CT device according to the second embodiment of the present invention is characterized by detecting a low current.

Further, the PCB material described in the present invention corresponds to any one of a flexible material and a rigid material.

That is, since the PCB is formed inside the breaker case, it is preferable to adopt the above material so that a shape thereof can be elastically changed according to the shape of the case.

In general, a method using a conventional CT device to detect low current or large current is the most accurate and ideal. However, a disadvantage is that the cost is high, and thus the conventional CT device has been applied only to an expensive product and has not been popularized. In particular, a CT structure is so large that the conventional CT device could not be applied to a small breaker.

However, the above problem could be improved through the present invention.

Specifically, since the air-core coil sensor is used, a saturation point is high, and thus a nearly linear output characteristic can be achieved.

Therefore, in the present invention, it is possible to detect an overload current corresponding to a fault current, that is, a large current (100 A to 10,000 A) using excellent linearity of the air-core coil sensor, and to detect a low current (several mA) when a magnetic core body is formed on the inside as necessary.

In addition, a problem of the breaker that an internal space is narrow due to a mechanical structure can be solved by forming the independent PCB CT device, thereby saving the cost and solving a problem of a space constraint.

Meanwhile, the air-core coil sensor not having the core layer of the second embodiment described in the present invention has difficulties in detecting a fine current. However, the air-core coil sensor operates at a large current of 2.5 to 20 times, and thus can detect overcurrent of B, C, and D types.

When the air-core coil sensor having the core layer therein is formed as in the third embodiment, a fine current can be detected.

As a result, the present invention provides the breaker capable of detecting an overload current (large current or low current) and at the same time detecting a leakage current.

On the other hand, in the case of the conventional coil-type ZCT device or CT device, the coil is wound using a winding machine, and thus a characteristic inevitably changes due to gap imbalance, cross generation, etc.

However, in the case of the present invention, since the pattern is formed while maintaining a constant interval, the overall shape of the patterns has a coil wound shape, thereby providing a uniform characteristic during mass production.

That is, when the coil is wound by the winding machine or by hand, the interval between coils may not be constant, and coils may be stuck together. In particular, it may be difficult to maintain a constant interval in a shape other than a circular shape.

For example, in the case of using the winding machine, only a circular detection element can be used. In a shape of an ellipse, a square having an angled corner, a triangle, etc., an interval is inevitably unbalanced, and thus a uniform characteristic may not be provided.

In addition, as the industrial structure develops day by day, the structure of industrial machines has been changed into various forms.

For example, in the case of a current detection element configured in a solar inverter, a circle is not suitable.

However, in the case of the present invention, it is possible to apply a variety of shapes to any industrial machine structure. Further, the grafting ability with the existing industrial machine structure is excellent while a manufacturing cost does not rise.

That is, since there is no human intervention and no mechanical error, the size can be miniaturized while providing uniform quality, and the synergistic effect of providing various types of CT detection elements can be obtained.

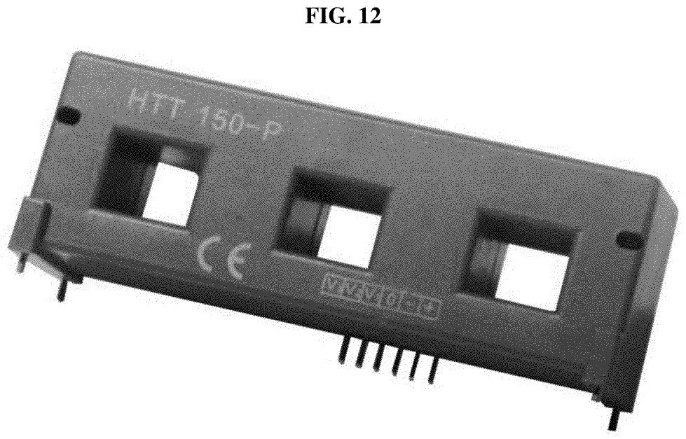

Meanwhile, since the IOT-based terminal is being released in the current Internet of Things era, it is necessary to detect the energy consumed by the terminal, so the most suitable CT device has been released as illustrated in FIG. 12.

However, for example, the existing CT device has a considerable size such as 10 cm or 20 cm, and thus may not be installed in a place where an installation space is limited.

In particular, the existing CT device is not applicable to the IOT terminal.

Accordingly, a thin and small CT device is required in a narrow installation space. In particular, the CT device needs to be embedded in the IOT terminal. However, the conventional CT device is an external device and may not be applied to the IOT terminal.

As a result, the present invention provides an ultra-slim CT device, thereby providing an advantage that the CT device can be embedded in the above-described IOT terminal.

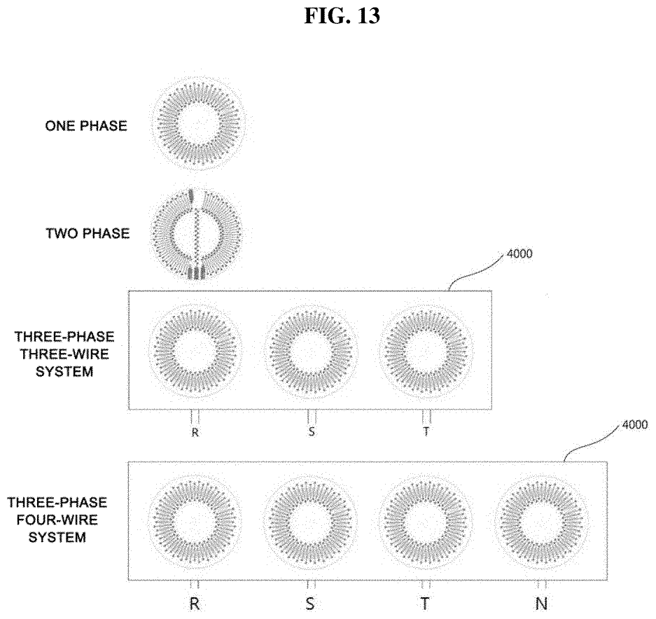

FIG. 13 is an illustrative view illustrating an external view when the independent type instantaneous current detection PCB CT device applied to the breaker according to the first embodiment to the third embodiment is applied to a one-phase to three-phase four-wire system.

As illustrated in FIG. 13, the independent type instantaneous current detection PCB CT device according to the first embodiment of the present invention can be applied to one phase, and the independent type instantaneous current detection PCB CT device according to the second embodiment or the third embodiment can be applied to two phases.

In addition, when the one-sphere type instantaneous current detection PCB CT device according to the first embodiment is applied to a three-phase three-wire system, it is sufficient that PCB CT devices are located at respective positions of through-holes of a base plate 4000 having three through-holes.

In addition, when the one-sphere type instantaneous current detection PCB CT device according to the first embodiment is applied to the three-phase four-wire system, it is sufficient that PCB CT devices are located at respective positions of through-holes of a base plate (4000) having four through-holes.

As such, it is possible to detect a current by simply mounting the independent type instantaneous current detection PCB CT device in a three-phase three-wire, three-phase four-wire, two-phase, or one-phase system, which is an advantage. Further, scalability is provided to allow application to a miniature IOT terminal, which needs to be configured on the inside.

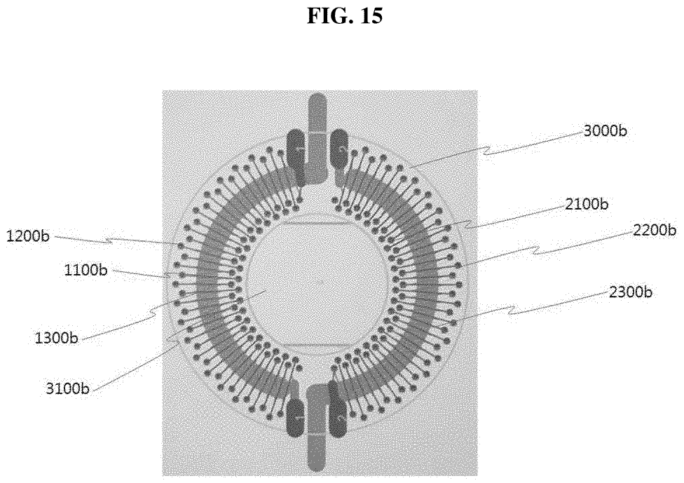

FIG. 15 is a schematic configuration diagram of an independent type instantaneous current detection PCB CT device applied to a breaker according to a fourth embodiment of the present invention.

As illustrated in FIG. 15, the independent type instantaneous current detection PCB CT device applied to the breaker is characterized by being mounted on a main PCB formed in the breaker or formed independently of the breaker by including a donut-shaped PCB (3000b) including a through-hole portion (3100b), a PCB type first air-core coil sensor (1000b) for detecting a current of an electric wire passing through a through-hole portion (3100b) formed in the PCB (3000b) by a plurality of inner via-holes (1100b) formed at a certain interval on one side of the through-hole portion (3100b), a plurality of outer via-holes (1200b) formed at a certain interval at locations spaced apart from the inner via-holes by certain intervals, and the inner via-holes and the outer via-holes connected by a coil pattern (1300b), and a PCB type second air-core coil sensor (2000b) for detecting a current of an electric wire passing through the through-hole portion (3100b) formed in the PCB (3000b) by a plurality of inner via-holes (2100b) formed at a certain interval on the other side of the through-hole portion (3100b), a plurality of outer via-holes (2200b) formed at a certain interval at locations spaced apart from the inner via-holes by certain intervals, and the inner via-holes and the outer via-holes connected by a coil pattern (2300b).

That is, one through-hole portion is configured, and the PCB type first air-core coil sensor (1000b) and the PCB type second air-core coil sensor (2000b) are configured on a left side and a right side of the through-hole portion, respectively.

In this instance, to detect a large current, the PCB type first air-core coil sensor (1000b) and the PCB type second air-core coil sensor (2000b) are characterized by including an upper coil pattern forming layer (100) formed of a nonmagnetic material and having a plurality of coil patterns (1300 and 2300) connected through inner via-holes (1100 and 2100) and outer via-holes (1200 and 2200) alternately from the upper side to the lower side and from the lower side to the upper side, an insulator (200) disposed below the upper coil pattern forming layer to have a plurality of via-holes (210) having the same size as that of the inner via-holes (1100 and 2100) and the outer via-holes (1200 and 2200) at positions thereof on both sides, and a lower coil pattern forming layer (300) located below the insulator, formed of a nonmagnetic material, and having a plurality of coil patterns (1300a and 2300a) connected through a plurality of inner via-holes (1100a and 2100a) and outer via-holes (1200a and 2200a) alternately from the upper side to the lower side and from the lower side to the upper side.

Meanwhile, to detect a low current, the PCB type first air-core coil sensor (1000b) and the PCB type second air-core coil sensor (2000b) are characterized by including an upper coil pattern forming layer (100) formed of a nonmagnetic material and having a plurality of coil patterns (1300 and 2300) connected through inner via-holes (1100 and 2100) and outer via-holes (1200 and 2200) alternately from the upper side to the lower side and from the lower side to the upper side, an insulator (200) disposed below the upper coil pattern forming layer to have a plurality of via-holes (210) having the same size as that of the inner via-holes (1100 and 2100) and the outer via-holes (1200 and 2200) at positions thereof on both sides, a magnetic core body (400) formed of a core material between the via-holes (210) formed on the both sides, and a lower coil pattern forming layer (300) located below the insulator, formed of a nonmagnetic material, and having a plurality of coil patterns (1300a and 2300a) connected through a plurality of inner via-holes (1100a and 2100a) and outer via-holes (1200a and 2200a) alternately from the upper side to the lower side and from the lower side to the upper side.

A difference from the first embodiment is that the PCB type air-core coil sensor is not continuously configured, and the PCB type first air-core coil sensor (1000b) and the PCB type second air-core coil sensor (2000b) are configured on one side and the other side of the through-hole portion.

In this instance, internal stacking of the PCB type first air-core coil sensor (1000b) and the PCB type second air-core coil sensor (2000b) is similar to that of the first embodiment or the second embodiment. To detect a large current, the upper coil pattern forming layer (100), the insulator (200), and the lower coil pattern forming layer (300) are included.

To detect a low current, the upper coil pattern forming layer (100), the insulator (200), the lower coil pattern forming layer (300), and the magnetic core body (400) are formed.

By providing the independent type instantaneous current detection PCB CT device including the coil pattern-based PCB type air-core coil sensor mounted on the main PCB formed in the breaker to ensure a space for forming the CT device on the breaker structure or configured independently of the breaker through the above-described configuration and operation, the breaker is provided to have an instantaneous detection function for blocking a short circuit or an overload when the short circuit or the overload occurs. Thus, a problem of a conventional art in which various current detection functions may not be performed due to lack of space is compensated, thereby providing an instantaneous function for simultaneously detecting a short circuit and an overload current.

In addition, as the independent type instantaneous current detection PCB CT device including the PCB type air-core coil sensor is configured inside the narrow earth leakage breaker case, and thus various analog parts are integrated on the PCB corresponding to the printed circuit board, it is effective in improving a humidity-resistant characteristic and reliability of product performance.

This invention can be implemented in many different forms without departing from technical aspects or main features. Therefore, the implementation examples of this invention are nothing more than simple examples in all respects and will not be interpreted restrictively.

### INDUSTRIAL APPLICABILITY

The present invention is provided to an independent type instantaneous current detection PCB CT device including a coil pattern-based PCB type air-core coil sensor mounted on a main PCB formed in the breaker or configured independently of the breaker, so that it may be widely used in the field of the circuit breakers.

1. An independent type instantaneous current detection PCB CT device applied to a breaker mounted on a main PCB formed in the breaker or formed independently of the breaker by including
a PCB (3000) including a first through-hole portion (3100) formed on one side of a partition and a second through-hole portion (3200) formed on the other side of the partition with the partition (3300) interposed therebetween,
a PCB type first air-core coil sensor (1000) for detecting a current of a first electric wire (L1) passing through the first through-hole portion (3100) by a plurality of inner via-holes (1100) formed at a certain interval on an outside of the first through-hole portion (3100) formed in the PCB (3000), a plurality of outer via-holes (1200) formed at a certain interval at locations spaced apart from the inner via-holes by certain intervals, and the inner via-holes and the outer via-holes connected by a coil pattern (1300), and
a PCB type second air-core coil sensor (2000) for detecting a current of a second electric wire (L2) passing through the second through-hole portion (3200) by a plurality of inner via-holes (2100) formed at a certain interval on an outside of the second through-hole portion (3200) formed in the PCB (3000), a plurality of outer via-holes (2200) formed at a certain interval at locations spaced apart from the inner via-holes by certain intervals, and the inner via-holes and the outer via-holes connected by a coil pattern (2300).

2. The independent type instantaneous current detection PCB CT device according to claim 1, wherein in the partition (3300), a plurality of partition via-holes (3310) are formed at a certain interval, and one of the partition via-holes and another one of the partition via-holes are connected by a coil pattern (3320).

3. The independent type instantaneous current detection PCB CT device according to claim 1,
wherein the PCB type air-core coil sensor (1000a) or the PCB type first air-core coil sensor (1000) and the PCB type second air-core coil sensor (2000) include
an upper coil pattern forming layer (100) formed of a nonmagnetic material and having a plurality of coil patterns (1300 and 2300) connected through the inner via-holes (1100 and 2100) and the outer via-holes (1200 and 2200) alternately from an upper side to a lower side and from the lower side to the upper side,
an insulator (200) disposed below the upper coil pattern forming layer to have a plurality of via-holes (210) having the same size as a size of the inner via-holes (1100 and 2100) and the outer via-holes (1200 and 2200) at positions thereof on both sides, and
a lower coil pattern forming layer (300) located below the insulator, formed of a nonmagnetic material, and having a plurality of coil patterns (1300a and 2300a) connected through a plurality of inner via-holes (1100a and 2100a) and outer via-holes (1200a and 2200a) alternately from an upper side to a lower side and from the lower side to the upper side.

4. The independent type instantaneous current detection PCB CT device according to claim 1, wherein in the partition (3300), a core layer (3300a) is formed.

5. The independent type instantaneous current detection PCB CT device according to claim 1,
wherein the PCB type first air-core coil sensor (1000) and the PCB type second air-core coil sensor (2000) include
an upper coil pattern forming layer (100) formed of a nonmagnetic material and having a plurality of coil patterns (1300 and 2300) connected through the inner via-holes (1100 and 2100) and the outer via-holes (1200 and 2200) alternately from an upper side to a lower side and from the lower side to the upper side,
an insulator (200) disposed below the upper coil pattern forming layer to have a plurality of via-holes (210) having the same size as a size of the inner via-holes (1100 and 2100) and the outer via-holes (1200 and 2200) at positions thereof on both sides,
a magnetic core body (400) formed of a core material between the via-holes (210) formed on the both sides, and
a lower coil pattern forming layer (300) located below the insulator, formed of a nonmagnetic material, and having a plurality of coil patterns (1300a and 2300a) connected through a plurality of inner via-holes (1100a and 2100a) and outer via-holes (1200a and 2200a) alternately from an upper side to a lower side and from the lower side to the upper side.

6. The independent type instantaneous current detection PCB CT device according to claim 1,
wherein PCB CT devices are located at respective positions of respective through-holes of a base plate (4000) in which three through-holes are formed when the independent type instantaneous current detection PCB CT device is applied to a three-phase three-wire system, or
PCB CT devices are located at respective positions of respective through-holes of a base plate (4000) in which four through-holes are formed when the independent type instantaneous current detection PCB CT device is applied to a three-phase four-wire system, and
the independent type instantaneous current detection PCB CT device is allowed to detect a current when the PCB CT device is embedded in an IOT terminal.

7. An independent type instantaneous current detection PCB CT device applied to a breaker mounted on a main PCB formed in the breaker or formed independently of the breaker by including
a donut-shaped PCB (3000b) including a through-hole portion (3100b),
a PCB type first air-core coil sensor (1000b) for detecting a current of an electric wire passing through a through-hole portion (3100b) formed in the PCB (3000b) by a plurality of inner via-holes (1100b) formed at a certain interval on one side of the through-hole portion (3100b), a plurality of outer via-holes (1200b) formed at a certain interval at locations spaced apart from the inner via-holes by certain intervals, and the inner via-holes and the outer via-holes connected by a coil pattern (1300b), and
a PCB type second air-core coil sensor (2000b) for detecting a current of an electric wire passing through the through-hole portion (3100b) formed in the PCB (3000b) by a plurality of inner via-holes (2100b) formed at a certain interval on the other side of the through-hole portion (3100b), a plurality of outer via-holes (2200b) formed at a certain interval at locations spaced apart from the inner via-holes by certain intervals, and the inner via-holes and the outer via-holes connected by a coil pattern (2300b).
